(19) United States
(12) Patent Application Publication
(10) Pub. No.: US 2011/0038440 A1
(43) Pub. Date: Feb. 17, 2011

(54) Process for Receiving a Signal and a Receiver

(75) Inventors: Oliver Balbach, Muenchen (DE); Jean-Jacques Floch, Muenchen (DE); Andreas Schmitz-Peiffer, Muenchen (DE)

Correspondence Address: CROWELL & MORING LLP;INTELLECTUAL PROPERTY GROUP, P.O. BOX 14300, WASHINGTON, DC, 20044-4300, US

(73) Assignees: Astrium GmbH, Taufkirchen (DE); IFEN GmbH, Poing (DE)

(21) Appl. No.: 12/837,942

(22) Filed: Jul. 16, 2010

(30) Foreign Application Priority Data
Jul. 17, 2009 (DE) 102009033788.1-35

(51) Int. Cl. H03D 3/00; H04B 1/10

(52) U.S. Cl. 375/334; 375/350

(57) ABSTRACT

A process for receiving a GMSK-modulated signal which, for simultaneously transmitting two services, has an in-phase signal with a pseudo-random code that differs from the quadrature signal. By means of a decomposition filter in a reference signal branch detects one service independently of the other during the correlating with the received signal.

This application claims the priority of German patent document 10 2009 033 788.1-35, filed Jul. 17, 2009, the disclosure of which is expressly incorporated by reference herein.

The invention relates to a process for receiving a phase-continuous signal and to a receiver.

### BACKGROUND OF THE INVENTION

GMSK (Gaussian minimum shift keying) is one of the most promising types of modulation for transmitting signals, such as communication signals or navigation signals, within a restricted bandwidth without interference with the adjacent bands.

In comparison to several other signals, advantages of this modulation pattern are:
Improved spectral efficiency in comparison to other keying modulation processes;
Constant envelope. The interferences because of the use of nonlinear amplifiers are thereby limited.

Currently, GMSK is used mainly in radio communication systems, such as the cellular GSM (Global System for Mobile Communications). So far, it has not been used by any navigation signals, and accordingly there have therefore also not been any navigation receivers that are based on this modulation pattern. However, the invention can also be applied to communication signals.

Navigation signals are signals which are emitted by fixed or mobile transmitters for the purpose of permitting at least one position indication in corresponding receivers. The position indication is not derived by taking a bearing (i.e., direction finding from, for example, the direction-dependent signal strength of the incoming signal), but by a propagation time determination of a signal. CDMA signals, which permit a correlation with a receiver-generated comparison signal, for example, are suitable for this purpose. CDMA-based navigation signals are distinguished particularly by a PRN (pseudo random noise) code, on which they are based, and by a data rate which is low in comparison to communication signals (for example, 0 bits/s for pilot channels to, for example, 1,000 bits/s for data channels). Current navigation systems use a data rate of 50 bits/s.

In the simplest case, the PRN code is multiplied by the data bits. However, it is also possible to multiply the PRN code or the data bits by another carrier (hereinafter referred to as a “subcarrier”). This subcarrier may, for example, be an unmodulated square wave signal, a so-called BOC (binary offset carrier) signal or a BCS (binary coded signal) signal. The HOC signal is explained below in greater detail, by means of FIG. 1.

As a result of the subcarrier, the frequency spectrum in the available bandwidth will be better utilized because, corresponding to the frequency of the subcarrier, the spectrum is shifted from the otherwise highly utilized center to the otherwise only slightly utilized edges of the frequency band. As a result, the frequency band is used more uniformly up to the edges.

As used herein, the term “service” refers to the transmission of a signal, wherein the physical signal itself (and/or the content of the signals modulated onto the physical signal) can be received only for an application and/or for a user group. An application is, for example, a commercial precision navigation application. A user group may be restricted or closed, such as commercial users or security agencies; however, it may also be public.

While the codes for the unrestricted signals are publicly known, the codes of the restricted signals are more or less strictly kept secret, depending on the application (commercial, security agencies, etc.). If it were necessary for the receiver to know the signal of the restricted service, there would be a risk that these codes could come into the possession of unauthorized persons. Also for this reason, there is considerable interest in being able to receive the services independently of one another.

The service may therefore contain a position signal that is more precise because of physical features of the channel or because of the digital signal structure; or it may contain additional information, such as additional integrity, ionosphere, troposphere information.

From the view of a transmitter on a satellite, it is desirable to emit as many services as possible by means of as few resources as possible. Thus, services which each use a CDMA code (or PRN code) can be transmitted, for example, on a complex GMSK channel 2.

A user receiver can now be adapted to a user group in that, from the beginning, it processes only the signals of this user group, and thus becomes less complex. Therefore, positive effects can be achieved, such as a lower price, lower power input, lower weight, etc.

When different services are transmitted by way of a channel, it is desirable to design the receiver such that only the signals of the one desired service must be processed.

Particularly applications using CDMA (code division multiple access) as the channel access method are considered in this invention. For example, a GMSK-modulated CDMA navigation signal is considered by way of which two services are transmitted simultaneously. In order to transmit two services simultaneously, the signal can be generated as a complex signal. (A complex signal is distinguished by the fact that it can be represented by two partial signals phase-shifted by 90°, which are thereby orthogonal and therefore mutually independent, and the signal can therefore also be correspondingly implemented.) The complex signal can be split into an I-branch (also called I-channel or In-phase channel) and a Q-branch (also called Q-channel or quadrature channel), in which case it is the goal to divide the input data flow such that the data of one service are transmitted on the one channel (such as the I-channel) and the data of the other service are transmitted on the other channel (such as the Q-channel). For this purpose, the input data flow is formed alternately from a data bit of the first service and a data bit of the second service.

Because of the ICCI (inter code chip interference) for GMSK, in contrast to OQPSK (offset quadrature phase shift keying), a mutually independent production of the PRN (pseudo random noise) codes of the in-phase and quadrature phase channels will not be possible. However, because of the poorer spectral characteristics, OQPSK is not suitable as a solution.

A confidentiality problem therefore exists when two independent services are sent by way of the I-channel and the Q-channel because, in order to receive one of the two services, the PRN code of the other service must be known in the receiver.

For example, a commercial service is reached because of the fact that the PRN code is not publicly known or coded. If, for example, by means of the navigation signal, a public and a commercial service are to be transmitted simultaneously, according to the state of the art, both codes would have to be known in the receiver in order to decode the signal, because a separation of the signal is not possible as a result of the inter code chip interferences. The inter code chip interferences in the adjacent ships originate from the respective other code and have to be taken into account during the correlating by the simulation of this other code.

Even if the receiver does not offer a commercial service, the receiver manufacturer would need to know the commercial code and implement the latter in the receiver. The risk therefore exists that the commercial code may be obtained by unauthorized persons.

One method according to the state of the art for solving the problem of the I-Q splitting is to use the so-called precoding technique which is also used in many communication systems. When precoding is used, the output signal polarity obtains the same preceding sign as the binary PRN code of the input signal. In this case, the receiver can correlate the incoming signal with its locally generated binary PRN code.

The following are three main disadvantages of the precoding technique:
A more complex transmitter design,
a power loss at the receiver,
an increase of the complexity in order to compensate the unavoidable code delay between the incoming RF signal and the locally generated binary PRN code. A performance comparable to the BPSK can be achieved only when the code delay and the phase shift are zero.

It should be noted here that the transmission in communication systems according to the state of the art does not concern the transmission of two different independent services but, on the contrary, the transmission of an input data flow (of one “service”), in which case, what matters is the transmission of the data flow of this service at a high data rate.

### SUMMARY OF THE INVENTION

One object of the invention, therefore, is to provide a receiver architecture by which two services, which are transmitted as a GMSK navigation signal, can be received independently of one another.

This and other objects and advantages are achieved by the method according to the invention, in which the Laurent decomposition is applied to the complex envelope of a GMSK signal. This technique permits a baseband navigation receiver architecture, in which the PRN codes can be generated independently of one another in an in-phase channel (I-channel) or in a quadrature channel (Q-channel).

The invention is based on the principle of using the C0 filter, which was calculated from the Laurent decomposition formula, for the service transmitted on the I- or Q-channel and of applying it to the desired PRN code for forming the reference signal which is used for correlating the transmitted CDMA signal. The reference signal can either be stored in a memory or it can be generated in real time.

Conventionally, the GMSK modulation is defined as an MSK modulation with a low-pass Gaussian filter. Another method of defining the transmitted baseband GMSK based over a period is the use of the Laurent decomposition, in which case the following applies:

$${S}_{Ref} \approx A {\sum }_{n = 1}^{L} ⌊ {a}_{n} \cdot {C}_{0} ( t - n {T}_{c} ) - {b}_{n} {a}_{n} {b}_{n - 1} \cdot {C}_{1} ( t - n {T}_{c} - \frac{{T}_{c}}{2} ) ⌋ + j A {\sum }_{n = 1}^{L} [ {b}_{n} \cdot {C}_{0} ( t - n {T}_{c} - \frac{{T}_{c}}{2} ) - {a}_{n} {b}_{n - 1} {a}_{n - 1} \cdot {C}_{1} ( t - n {T}_{c} ) ]$$

Wherein

A . . . signal amplitude

For a BPSK signal form:

aₙ . . . n-th PRN chip of the signal which is transmitted by way of the BPSK in-phase channel;

bₙ . . . n-th PRN chip of the signal which is transmitted by way of the BPSK quadrature phase channel;

L . . . PRN code length; and

Tc . . . chip period.

For a BOCs (m,n) (binary offset carrier sine with m=subcarrier rate and n=chip rate) or BOC_{c} (m,n) (binary offset carrier cosine), the signal form is inserted into the code sequence.

Other objects, advantages and novel features of the present invention will become apparent from the following detailed description of the invention when considered in conjunction with the accompanying drawings.

### BRIEF DESCRIPTION OF THE DRAWINGS

FIG. 1 is a view of a BOC (binary offset code) signal;

FIGS. 2A to 2C are views of Laurent curves according to an embodiment of the invention;

FIGS. 3A to 3C are views of quantization effects according to an embodiment of the invention;

FIG. 4 is a view of multipath signals according to an embodiment of the invention;

FIG. 5 is a view of a receiver architecture according to an embodiment of the invention; and

FIG. 6 is a view of a further receiver architecture according to an embodiment of the invention.

### DETAILED DESCRIPTION OF THE DRAWINGS

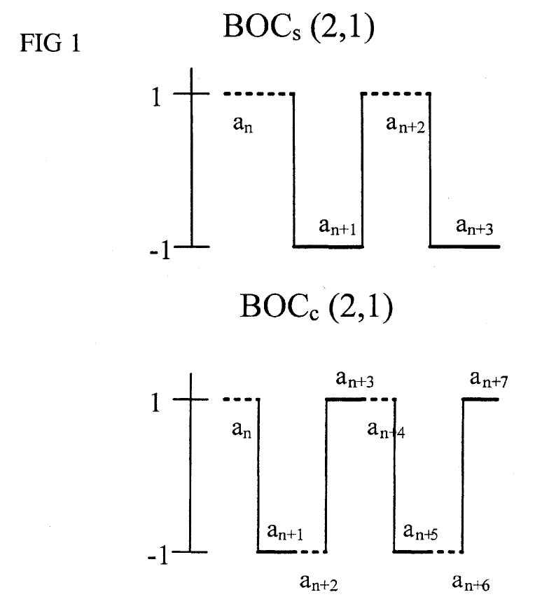

FIG. 1 illustrates the value of an in the case of BOCs or BOC_{c}. The same approach applies to the PRN code bn.

For BOCₛ, the PRN code length is

$$L \cdot \frac{n}{2 m} ,$$

and Tc represents the subchip length,

$$( {T}_{chipperiod} \frac{n}{2 m} ) ,$$

wherein L represents the number of subcarrier chips during a PRN code period (T_{chipperiod}) and represents the length of a PRN chip.

For BOC_{c}, the PRN code length is

$$L \cdot \frac{n}{4 m} ,$$

and Tc represents the subchip length

$$( {T}_{chipperiod} \frac{n}{4 m} ) .$$

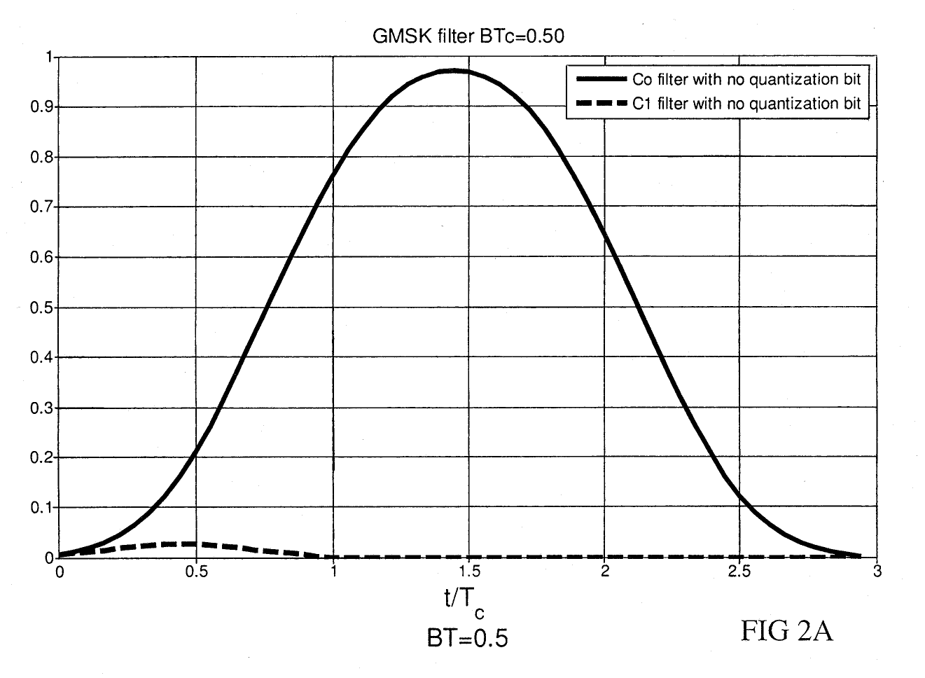

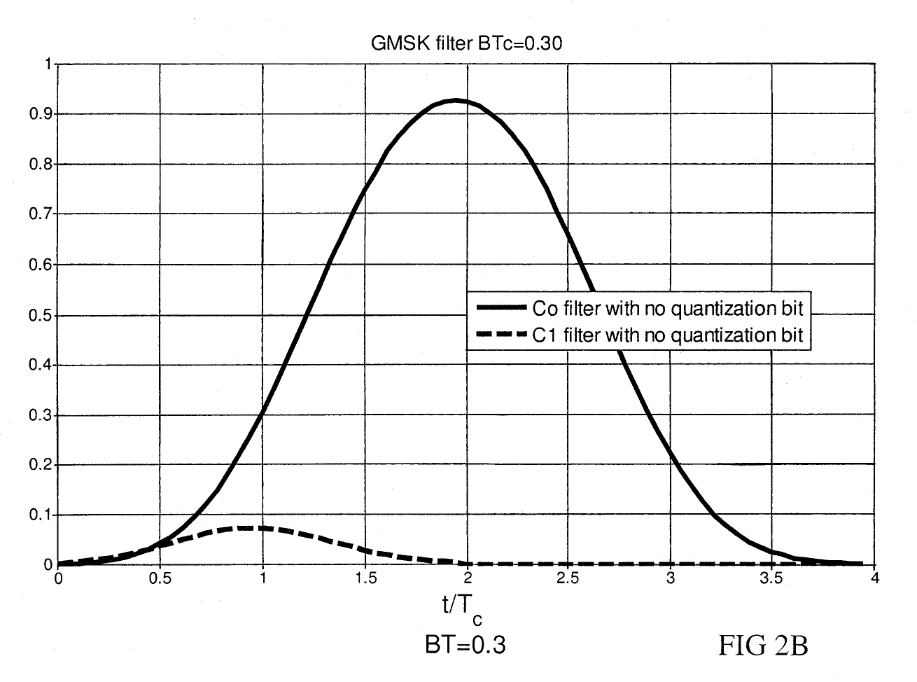

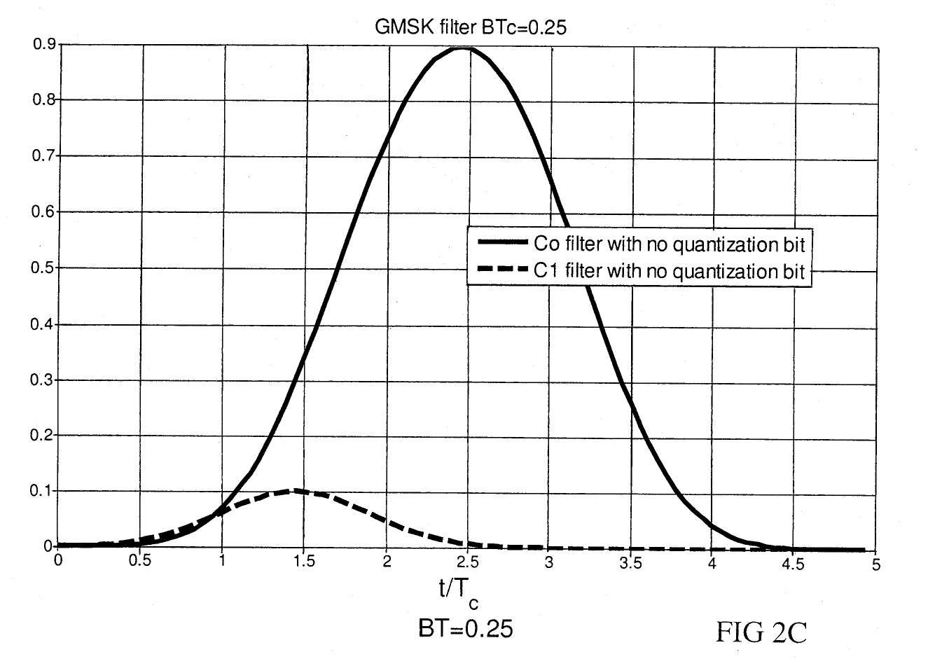

In FIGS. 2A-2C, C0 and C1 are shown for the following BT products: BTc=0.5, BTc=0.3 and BTc=0.25.

Based on the Laurent decomposition of the complex envelope of the GMSK signal, the baseband navigation receiver architecture can independently generate the PRN codes of the in-phase and of the quadrature channel. This is based on the principle of utilizing the C0 filter, which was calculated from the Laurent decomposition formula, for the service transmitted on the I- or Q-channel, and applying it to the desired PRN code to form the reference signal that is used to correlate the transmitted CDMA signal.

The architecture design is based on the following signal:

$${S}_{Receiver} = {\sum }_{n = 1}^{L} [ {a}_{n} \cdot {C}_{0} ( t - n {T}_{c} ) ]$$

For receiving only the Q-channel, the receiver will generate the following signal:

$${S}_{Receiver} = j A {\sum }_{n = 1}^{L} [ {b}_{n} \cdot {C}_{0} ( t - n {T}_{c} - \frac{{T}_{c}}{2} ) ]$$

For receiving Q-channel and the I-channel, on the other hand, the receiver will generate the following signal:

$${S}_{Receiver} = {\sum }_{n = 1}^{L} [ {a}_{n} \cdot {C}_{0} ( t - n {T}_{c} ) ] + j A {\sum }_{n = 1}^{L} [ {b}_{n} \cdot {C}_{0} ( t - n {T}_{c} - \frac{{T}_{c}}{2} ) ]$$

In order to improve the signal performance in a multipath environment, the filter C0 is quantized by means of 2 bits (one bit for the quantity and one bit for the preceding sign).

This architecture, which is very easy to implement, improves the performance in a multipath environment and provides a strict separation into an I- and Q-phase, so that an individual service is available to the user.

According to an embodiment of the invention, a process is provided for receiving a signal, the signal being complex and phase-continuously modulated and being correlated with a receiver-generated signal. The received signal as well as the receiver-generated signal is based on a pseudo-random code. In this case, the generation of the receiver-generated signal has the steps of generating the pseudo-random code sequence and of filtering the signal by means of a decomposition filter. Instead of the decomposition filter, other filters, such as a Nyquist filter, a matched filter, a Gauss filter, etc. would also be conceivable.

According to an embodiment of the invention, the decomposition filter is a Laurent decomposition filter, only the main component of which is used. Although a use of additional components would also be conceivable, these are negligible with respect to the performance and would only unnecessarily increase the complexity of the receiver. By using only the main component, the separate reception of an individual service becomes possible when two independent services are transmitted on the received signal. If higher Laurent components were used, independent reception of these two services would no longer be possible.

According to an embodiment of the invention, the received signal is generated from an analog signal that is scanned by means of one or more bits.

According to an embodiment of the process of the invention, the receiver-generated signal is quantized by one or more bits. As a result of the quantization, the correlation function becomes more acute, thereby reducing the error by multipath propagation and decreasing the complexity of the receiver.

According to another feature of the invention, the received signal may comprise two mutually independent pseudo-random codes. The receiver-generated signal also comprises one of the two pseudo-random codes and is filtered either in the in-phase channel or the quadrature channel.

Finally, the filtered signal is correlated with the received signal. Thus, as a result of the correlation, precisely one of the two services contained in the received signal will be detected without the requirement that the pseudo-random code of the other service has to be known.

According to an embodiment of the invention, the received signal comprises a first pseudo-random-code code and a second pseudo-random-code code that is not dependent on the first pseudo-random-code code. Furthermore, the receiver additionally generates a second signal, which comprises a second pseudo-random code, in which case, the receiver generated first and the second pseudo-random code are generated independently of one another. The first pseudo-random-code code is filtered in the in-phase channel by means of a first decomposition filter, while the second pseudo-random-code code is filtered in the quadrature channel by means of a second decomposition filter. The filtered first pseudo-random code is correlated with the received signal, and the filtered second pseudo-random code is correlated with the received signal.

As a result, a second line of a receiver-generated signal is added, which line finally generates a second receiver-generated signal which contains the pseudo-random code of the second service. The second service can thereby also be received independently of the first service, and can be received or detected simultaneously with the first service. It is also possible to switch between the services or, depending on the requirements, to switch off one of the two services.

According to an embodiment of the invention, the pseudo-random-code is modulated by means of a subcarrier. Likewise, the receiver-generated pseudo-random code can be modulated by means of the subcarrier. The subcarrier may, for example, be a square wave signal which has the same rate as the pseudo-random code or a higher rate than the pseudo-random code, as, for example, a BOC signal or a BCS signal. Naturally, other signal forms are also conceivable here.

According to an embodiment of the invention, the received phase-continuous signal is a GMSK which is modulated by means of data bits. More precisely, as known to a person skilled in the art, the pseudo-random code is multiplied by the data bits and possibly by a subcarrier, and the resulting bit sequence is GMSK-filtered.

The received signal can, for example, be assigned to one of the following signal groups: Navigation signal, communication signal, television signal, radio signal, etc.

According to an embodiment of the invention, two services are transmitted on these signals, as explained above. These services may, for example, be free services, such as free television programs, commercial services, as, for example, pay television, safety-relevant services, etc. Any mixture of these types of services is also conceivable; it would, for example, be possible to receive a normal-quality program on a channel, such as the in-phase channel, free-of-charge and to receive the same program in HDTV (high-definition television) on the Q-channel as a paid program. It would then also be possible for the user to switch-over to the HDTV program and to pay for it only if he watches this high-quality program.

According to an embodiment of the invention, the receiver-generated signal is generated from predefined values filed in a memory. This means that the signal is not generated in real time but is already present as values filed in a memory. This simplifies the receiver design, permits a simple change of the signals and allows rapid processing. It would also be conceivable that values are generated for the entire receiver-generated signal by means of the process, which values can be filed in a memory and can be correlated directly with the received signal. Then finally, instead the signal generating branch, only one or more memories will be necessary in the receiver, from which memory (memories) these values can be retrieved.

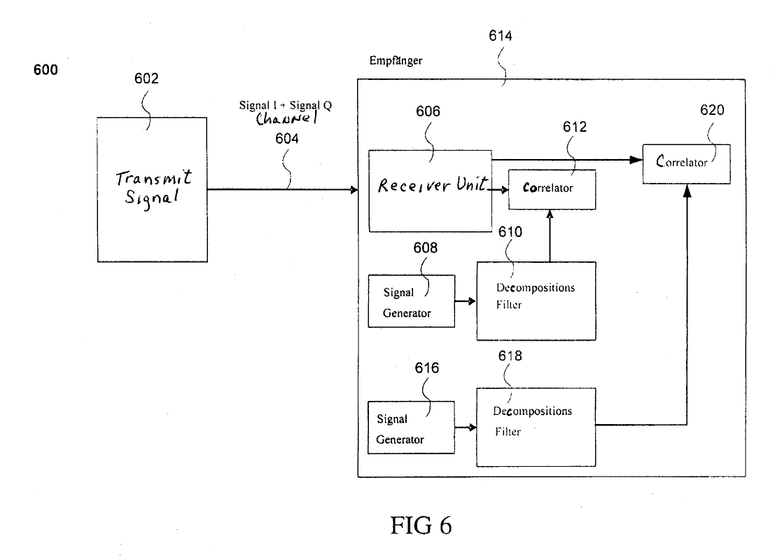

As illustrated in FIG. 6, according to an embodiment of the invention, a receiver 614 is provided for receiving phase-continuous signals 604, based on two independent input signals, the first input signal being an in-phase signal and the second input signal being a quadrature signal. Each input signal comprises a pseudo-random code. The receiver 614 has a receiving unit 606 for receiving the receive signal 604 and a first signal generator 608 which generates a first pseudo-random code signal corresponding to a first of the two pseudo-random codes of the receive signal. According to this embodiment, the receiver 614 has a first decomposition filter 610, which filters the generated first pseudo-random code signal, and a first correlator unit 612 in order to correlate the filtered first pseudo-random code signal with the receive signal 604.

As a result, the receiver 614 can detect one service from the two services which are transmitted on the receive signal.

The explanations concerning the above-described process analogously apply to the receiver.

According to an embodiment of the invention, the receiver 614 has a second signal generator 616 which generates a second pseudo-random code signal corresponding to the second of the two pseudo-random codes of the receive signal. Furthermore, the receiver has a second decomposition filter 618 which filters the generated second pseudo-random code signal. The receiver 614 also has a second correlator unit in order to correlate the filtered second pseudo-random code signal with the receive signal 604.

As a result, the receiver 614 can simultaneously or selectively receive and detect both services which are transmitted by means of the receive signal 604.

According to an embodiment of the invention, the correlator unit 612 and 620 respectively comprises at least one of the following correlator types:
An early-late correlator
a delta correlator
a multi-correlator.

In this case, a multi-correlator is, for example, also a correlator which detects only the timely signal or, for example, also a correlator which has n early and n late branches.

According to an embodiment of the invention, the signal generator 608 or 616 comprises at least one memory containing predefined signal values.

According to an embodiment of the invention, the receiver 614 comprises a quantization unit in order to quantize the received signal by means of one or more bits and/or a quantization unit in order to quantize the receiver-generated signal by means of one or more bits.

In the following, the invention will be explained in detail by reference to a further embodiment.

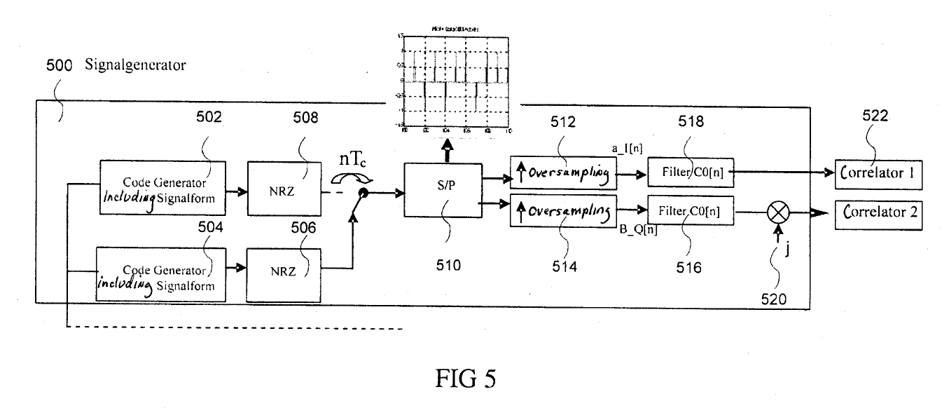

The receiver architecture illustrated in FIG. 5 has the capability of receiving the I-channel as well as the Q-channel. In order to receive the reference signal on the I-channel, only the path 502, 508, 510, 512, 518 needs to be implemented. As soon as the reference signal has been generated, it can be used for correlating the signal from the transmitter. As a result, every receiver which uses correlation functions can use this approach for receiving the GMSK signals.

The correlation function of a GMSK signal, which was modulated by means of PRN codes, is not as “sharp” as the corresponding BPSK (binary phase shift keying) signals. For this reason, the correlation function has a poorer performance in a multipath environment. A simple method of improving the performance is to use a 2-bit quantized reference signal for the filter C0.

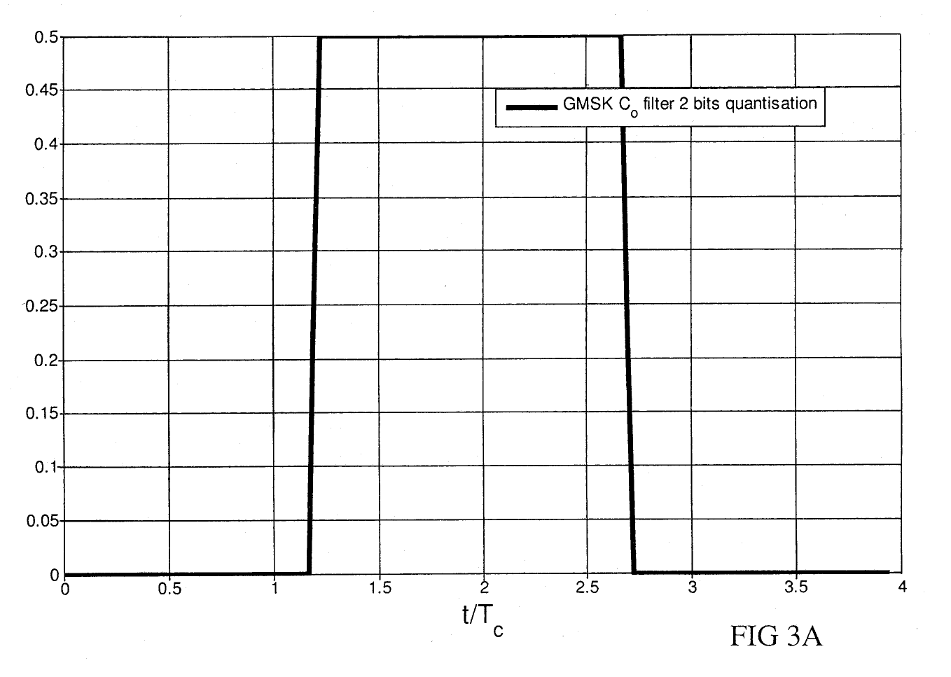

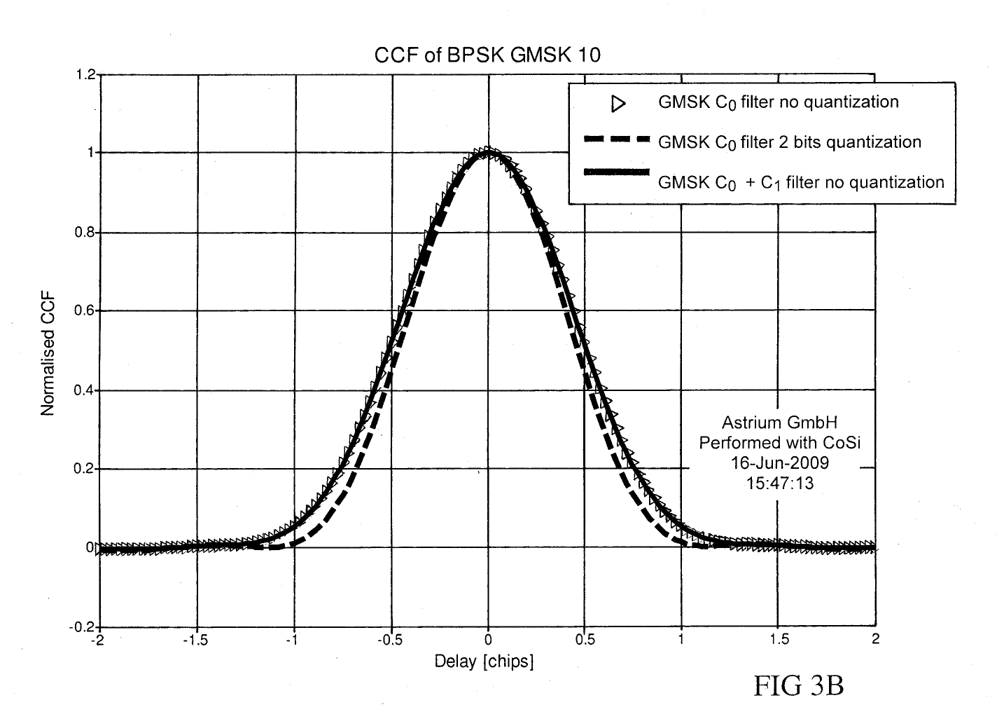

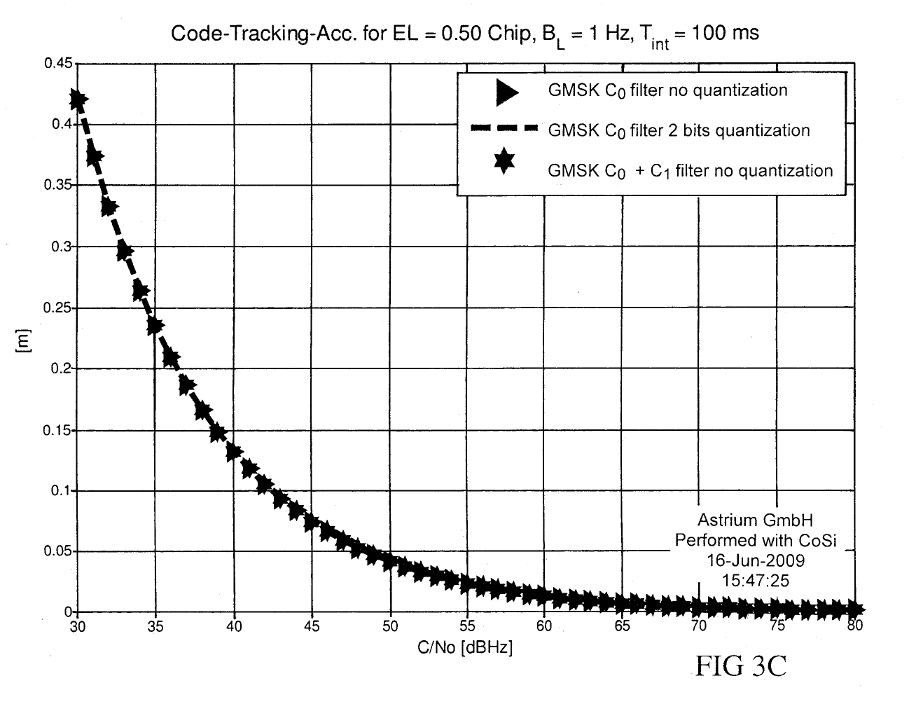

In order to sharpen the correlation, the filter C0 (516 or 518) is quantized by means of two bits during the scanning 512 or 514 (one bit for the quantity, one bit for the preceding sign), the implementation also being simplified. FIG. 3A illustrates this quantized signal.

In this manner, the performances are improved in a multi-path environment. FIG. 3B shows the cross correlation function (CCF) of a BPSK 10 GMSK (BTc=3) signal from a transmitter that was correlated with a corresponding receiver reference signal while using
the accurately transmitted signal with C0 and C1 without any quantization,
the signal with only C0 without any quantization,
the signal with only C0 with 2-bit quantization.

The power loss as a result of the use of only C0 without any quantization amounts to less than 0.1 dB, and to less than 0.7 dB, when C0 is used with a 2-bit quantization.

FIG. 3C shows an example of a code tracking of a BPSK 10 GMSK (BTc=0.3) signal in an AWGN (additive white Gaussian noise, superimposed white Gaussian noise) environment with an early-late spacing of 0.5 chips. It illustrates that the generation of the signal, as it is introduced in this invention, is similar to the more complex architecture with a C0+C1 filter or a C0 filter without quantization.

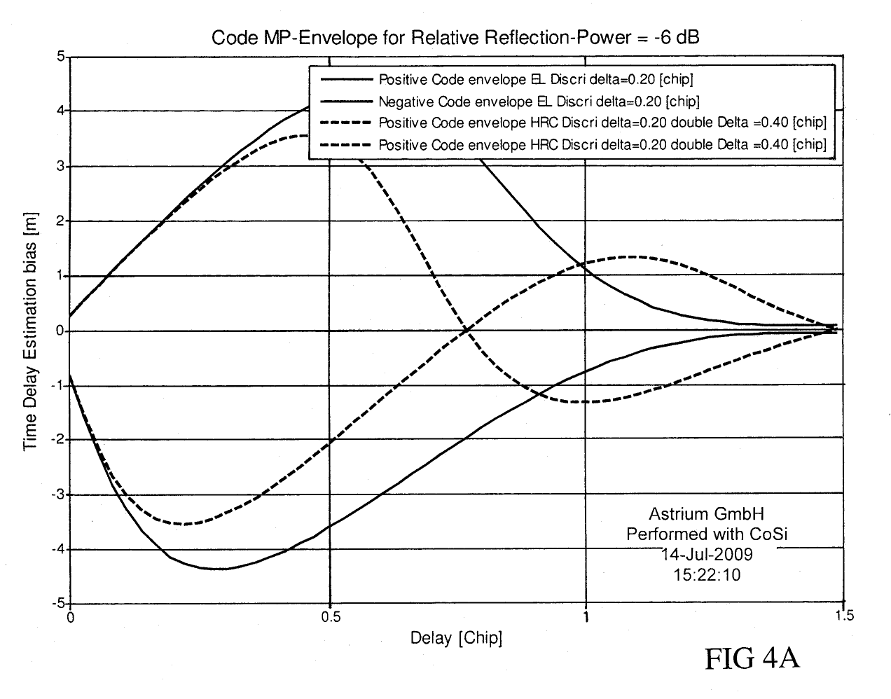

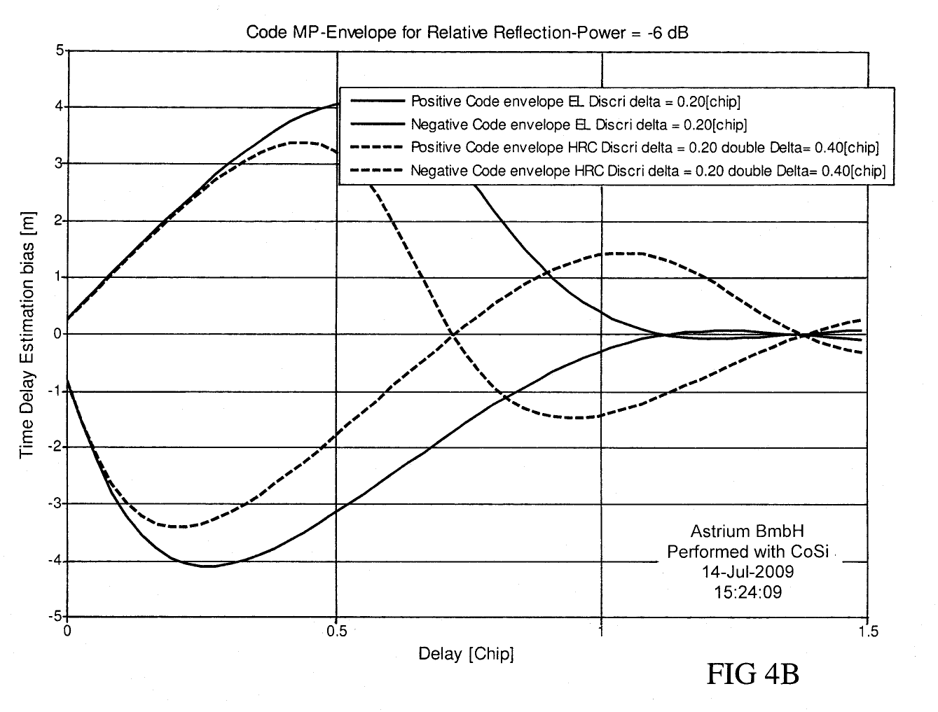

In order to show the improvement as a result of the use of a signal with C0 and 2-bit quantization, for these two cases, FIGS. 4A (C0 without quantization) and 4B (C0 with 2-bit quantization) illustrate the multipath envelope.

A comparison of FIG. 4A and FIG. 4B shows that the curves in FIG. 4B drop earlier. When a two-bit quantization filter is used, a multi-path, which arrives 1.25 chips after the main signal, has no influence on the tracking. This is not so for a non-quantized filter. In addition, the quantities of the errors are also slightly better when a two-bit quantization filter is used.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

What is claimed:

1. A process for receiving a complex and phase-continuously modulated signal, the signal being correlated with a receiver-generated signal, wherein:
the received signal is based on at least a first pseudo-random code;
the receiver-generated signal is based on at least a second pseudo-random code; and
generation of the receiver-generated signal includes
generating a second pseudo-random code signal comprising the second pseudo-random code that corresponds to the at least a first pseudo-random code; and
filtering the second pseudo-random code signal by means of a decomposition filter.

2. The process according to claim 1, wherein:
the decomposition filter is a Laurent decomposition filter; and
only a main component of the Laurent decomposition filter is used.

3. The process according to claim 1, wherein the received signal is generated from an analog signal scanned using at least one bit.

4. The process according to claim 1, wherein the receiver-generated signal is quantized using at least one bit.

5. The process according to claim 1, wherein:
the received signal comprises two mutually independent pseudo-random codes;
the receiver-generated signal comprises one of the two pseudo-random codes;
the receiver-generated signal is filtered in one of an in-phase channel and a phase quadrature channel; and
the filtered signal is correlated with the received signal.

6. The process according to claim 1, wherein:
the received signal comprises a first pseudo-random-code code and a second pseudo-random-code code that is independent of the first pseudo-random-code code;
the receiver also generates a second signal which comprises a second pseudo-random code;
the receiver-generated first and the second pseudo-random codes are generated independently of one another;
the first pseudo-random-code code is filtered in an in-phase channel by a first decomposition filter;
the second pseudo-random-code code is filtered in a quadrature channel by a second decomposition filter;
the filtered first pseudo-random code is correlated with the received signal; and
the filtered second pseudo-random code is correlated with the received signal.

7. The process according to claim 1, wherein:
the pseudo-random code is modulated using a subcarrier;
the receiver-generated pseudo-random code is also modulated by the subcarrier.

8. The process according to claim 1, wherein the received phase-continuous signal is a GMSK signal and is modulated by means of data bits.

9. The process according to claim 1, wherein the received signal is assignable to one of the signal groups:
a navigation signal;
a communication signal;
a television signal; and
a radio signal.

10. The process according to claim 1, wherein the receiver-generated signal is generated from predefined values filed in a memory.

11. A receiver for receiving a phase-continuous receive signal that is based on first and second independent input signals, each of which comprises a pseudo-random code, the first input signal being an in-phase signal, and the second input signal being a quadrature signal; said receiver comprising:
a receiving unit for receiving the receive signal;
a first signal generator which generates a first pseudo-random-code code signal corresponding to the first of the two pseudo-random-code code signals of the receive signal;
a first decomposition filter which filters the generated first pseudo-random-code code signal; and
a first correlator unit that correlates the filtered first pseudo-random code signal with the receive signal.

12. The receiver according to claim 11, further comprising a second signal generator which generates a second pseudo-random code signal corresponding to the second of the two pseudo-random-code codes of the receive signal; wherein the receiver has:
a second decomposition filter which filters the generated second pseudo-random code signal; and
a second correlator unit for correlating the filtered second pseudo-random code signal with the receive signal.

13. The receiver according to claim 11, wherein:
the correlator unit comprises at least one of an early-late correlator, a delta correlator, and a multi-correlator.

14. The receiver according to claim 11, wherein the signal generator comprises at least one memory that contains predefined signal values.

15. The receiver according to claim 11, further comprising at least one of:
a first quantization unit for quantizing the received signal by one or more bits; and
a second quantization unit for quantizing the receiver-generated signal by one or more bits.

16. A process for receiving a complex and phase-continuously modulated receive signal that is based on a pseudo-random code, said process comprising:
a signal generator generating a pseudo-random code signal that corresponds to the pseudo-random code of the receive signal;
a decomposition filter filtering the pseudo-random code signal to provide a receiver generated signal; and
a correlation unit correlating the receive signal with the receiver-generated signal.
